(19) United States
(12) Patent Application Publication
(10) Pub. No.: US 2008/0150039 A1
(43) Pub. Date: Jun. 26, 2008

(54) Semiconductor device

(76) Inventor: Hiroki Aisawa, Tsuruoka (JP)

Correspondence Address: HARNESS, DICKEY & PIERCE, P.L.C., P.O. BOX 828, BLOOMFIELD HILLS, MI, 48303, US

(21) Appl. No.: 12/011,976

(22) Filed: Jan. 30, 2008

Related U.S. Application Data
(62) Division of application No. 11/337,850, filed on Jan. 23, 2006.

(30) Foreign Application Priority Data
Feb. 28, 2005 (JP) 2005-054610

(51) Int. Cl. H01L 29/78

(52) U.S. Cl. 257/384; 257/E29.255

(57) ABSTRACT

A semiconductor device, including: a semiconductor substrate; a first gate insulation film installed on the semiconductor substrate; a first gate electrode installed on the first insulation film; a silicon oxide film, installed beneath a periphery of the first gate electrode, being thicker than the first gate insulation film; a source and a drain installed on the semiconductor substrate; an interlayer insulation film installed above the semiconductor substrate; a pad electrode installed on the interlayer insulation film; a passivation film, installed on the pad electrode, having an orifice above the pad electrode; and a bump electrode, installed in the orifice, located vertically above the part of or the entire first gate electrode.

### CROSS REFERENCE TO RELATED APPLICATIONS

This application is a divisional patent application of U.S. Ser. No. 11/337,850 filed Jan. 23, 2006, claiming priority to Japanese Patent Application No. 2005-054610 filed Feb. 28, 2005, all of which are incorporated by reference.

### BACKGROUND

1. Technical Field

The present invention relates to a semiconductor device, methods for manufacturing and designing thereof, particularly to techniques which prevents cracking of the insulation film under gate electrodes in regions beneath bump electrodes.

2. Related Art

FIG. 7A is a sectional drawing showing an exemplary structure of a semiconductor device 200 in an example of a related art. As shown in FIG. 7A, the semiconductor device 200 includes: a silicon substrate 1; a MOS transistor 80 formed on the silicon substrate 1; an interlayer insulation film 21, installed on the silicon substrate 1, covering the MOS transistor 80; an aluminum pad (hereafter “Al pad”) 31 installed on the interlayer insulation film 21; a passivation film 33, installed on the interlayer insulation film 21, covering the periphery of the top surface of the Al pad 31; and a bump electrode 41 installed on the Al pad 31 which is exposed from beneath the passivation film 33. In the semiconductor device 200, the reduction of chip area is achieved with a structure in which the Al pad 31 is formed above the MOS transistor 80 via the interlayer insulation film 21.

An example of this type of related art is disclosed in JP-A-2002-151465. As described in the example, a semiconductor device, in which a slit is formed on an Al pad formed on a semiconductor element, is disclosed. This semiconductor device allows achieving a minute chip, by containing the Al pad on the semiconductor element. Further, the slit reduces the effect caused by stresses such as thermal stress of aluminum, thereby supressing the cracking of the interlayer insulation film.

The chip area reduction (achieving a minute chip) is indeed possible with semiconductor devices such as the semiconductor device 200 shown in FIG. 7A and the semiconductor device disclosed in the above example.

The inventors of the present invention formed a test element group (hereafter “TEG”) with the structure shown in FIG. 7A, packaged the TEG to a wiring substrate, and operated it. As a result, the inventors encountered a problem that there were many current leaks (voids) in the MOS transistors located right beneath the bump electrodes, between the gate electrodes and the silicon substrate, while there were almost no current leaks described above, in the MOS transistors located in the region away from the direction right beneath the bump electrodes.

By further analysis of the current leak routes in this problem using hot-electron analyzer, the inventors came to learn that there were cracks formed in a gate oxidation film 82 under the edge of a gate electrode 81, as shown in FIG. 7B, and the current was leaking between the gate electrode 81 and the silicon substrate 1 through these cracks. Such cracking under the edge of the gate electrode 81 and the current leak through the cracks is discovered to have high incidences in the TEG, particularly, where the gate oxidation film 82 is formed in the thickness no more than 150 Å.

### SUMMARY

The advantage of the invention is to provide a semiconductor device, methods for manufacturing and designing thereof, in which the cracking of the insulation films under gate electrodes, caused by the stress during packaging, is prevented.

According to a first aspect of the invention, in order to achieve the aforementioned advantage, the semiconductor device includes: at least one transistor installed on a semiconductor substrate; an interlayer insulation film installed on the semiconductor substrate, covering the transistor; and a bump electrode installed on the interlayer insulation film via a pad. Here, in a region beneath the bump electrode, only one kind of transistor, in which an insulation film under the periphery-of a gate electrode is thicker than the insulation film under the central area of the gate electrode, is installed on the semiconductor substrate. In contrast, in the rest of the region of the semiconductor substrate, the other kind of transistor, in which the thickness of the insulation film under the central area of the gate electrode and the thickness of the insulation film under the periphery of the gate electrode are the same, is installed.

This structure allows prevention: of cracking in the insulation film for one kind of transistor formed in the region beneath the bump electrode, caused by the stress during packaging; and of a current leak between the gate electrode and the semiconductor substrate via the crack.

According to a second aspect of the invention, in the semiconductor device, the thickness of the insulation film under the central area of the gate electrode of one kind of transistor, the thickness of the insulation film under the gate electrode of the other kind of transistor, are the same. Here, ‘the same’ includes both cases where the values of thicknesses in the insulation film are identical, and where there is a slight fluctuation, even though the thicknesses in design are identical, caused during the process of deposition, in other words, approximately the same.

In the semiconductor device according to the second aspect of the invention, the electric characteristics of one kind of transistor and the other kind of transistor, such as a threshold voltage, may be approximately the same.

According to a third aspect of the invention, in the semiconductor device according to the first and the second aspects of the invention, the one kind of transistor has a local oxidation of silicon (hereafter referred to as LOCOS) offset structure. The LOCOS offset structure means that only the insulation film under the periphery of the gate electrode is thickened by the LOCOS process.

In the semiconductor device according to the third aspect of the invention, the insulation film under the periphery of the gate electrode may be thickened simultaneously with the formation of a LOCOS layer for elements separation on the semiconductor substrate. Hence, only the small number of additional processes for film thickening is required.

According to a forth aspect of the invention, in the semiconductor device according to the first or the second aspect of the invention, the one kind of transistor has a high temperature oxide (hereafter referred to as HTO) offset structure. The HTO offset structure means that only the insulation film under the periphery of the gate electrode is thickened by a selective formation of the HTO.

In the semiconductor device according to the forth aspect of the invention, the size of the semiconductor element may be made smaller compared to the second aspect of the invention, since there is no bird beak typically found in the LOCOS oxide.

According to a fifth aspect of the invention, in the semiconductor device according to the first or the second aspect of the invention, the one kind of transistor described above has a shallow trench isolation (hereafter referred to as STI) offset structure. The STI offset structure means that only the insulation film under the periphery of the gate electrode is thickened by the STI process.

In the semiconductor device according to the fifth aspect of the invention, the size of the semiconductor element may be made smaller compared to the second aspect of the invention, since there is no bird beak typically found in the LOCOS oxide. Moreover, the insulation film under the periphery of the gate electrode may be thickened simultaneously with the formation of the STI layer for component separation on the semiconductor substrate. Hence, compared to the third aspect of the invention, only the small number of additional processes for film thickening is required, since no HTO formation in a separate process is required for film thickening.

According to a sixth aspect of the invention, a method for manufacturing the semiconductor device includes: forming at least one transistor on a semiconductor substrate; forming an interlayer insulation film on the semiconductor substrate, so as to cover the transistor; and forming a bump electrode on the interlayer insulation film via a pad. When forming at least one transistor on the semiconductor substrate, only one kind of transistor, in which an insulation film under a periphery of a gate electrode is thicker than the insulation film under a central area of the gate electrode, is formed beneath a region in which the bump electrode is formed. In contrast, the other kind of transistor, in which the thickness of the insulation film under the central area of the gate electrode and under the periphery of the gate electrode are the same, is formed on the semiconductor substrate in the rest of the region.

This structure allows prevention of: cracking in the insulation film of the transistor formed in the region beneath the bump electrode, caused by the stress during packaging; and the current leak through the crack.

According to a seventh aspect of the invention, a method for designing a semiconductor device includes the following processes described later in this paragraph. Here, the semiconductor device includes: at least one transistor installed on a semiconductor substrate; an interlayer insulation film installed on the semiconductor substrate, covering the transistor; and a bump electrode installed on the interlayer insulation film, via a pad. The method for designing the semiconductor device includes: a process for detecting the location of the bump electrode; a process for identifying the transistor installed beneath the detected location; a process for defining only the identified transistor to one kind of transistor, in which an insulation film under a periphery of a gate electrode is thicker than the insulation film under a central area of the gate electrode, and defining the rest to the other kind of transistor, in which the thicknesses of the insulation film under the central area of the gate electrode and under the periphery of the gate electrode are the same.

This structure allows prevention of: cracking in the insulation film of the transistor installed in the region beneath the bump electrode, caused by the stress during packaging; and the current leak through the crack.

### BRIEF DESCRIPTION OF THE DRAWINGS

The invention will be described with reference to the accompanying drawings, wherein like numbers reference like elements.

FIGS. 1A and 1B are drawings showing an exemplary structure of a semiconductor device 100 and a MOS transistor 10 in a first embodiment.

FIG. 2 is a drawing showing an exemplary structure of a MOS transistor 70.

FIG. 3 is a flow chart showing a method for manufacturing the semiconductor device 100.

FIG. 4 is a drawing showing an exemplary structure of a MOS transistor 50 in a second embodiment.

FIGS. 5A to 5D represent a flow chart showing a method for manufacturing the semiconductor device 100′.

FIG. 6 is a drawing showing an exemplary structure of a MOS transistor 60 in a third embodiment.

FIGS. 7A and 7B are drawings showing an exemplary structure of a semiconductor device 200 in a related art and a problem thereof.

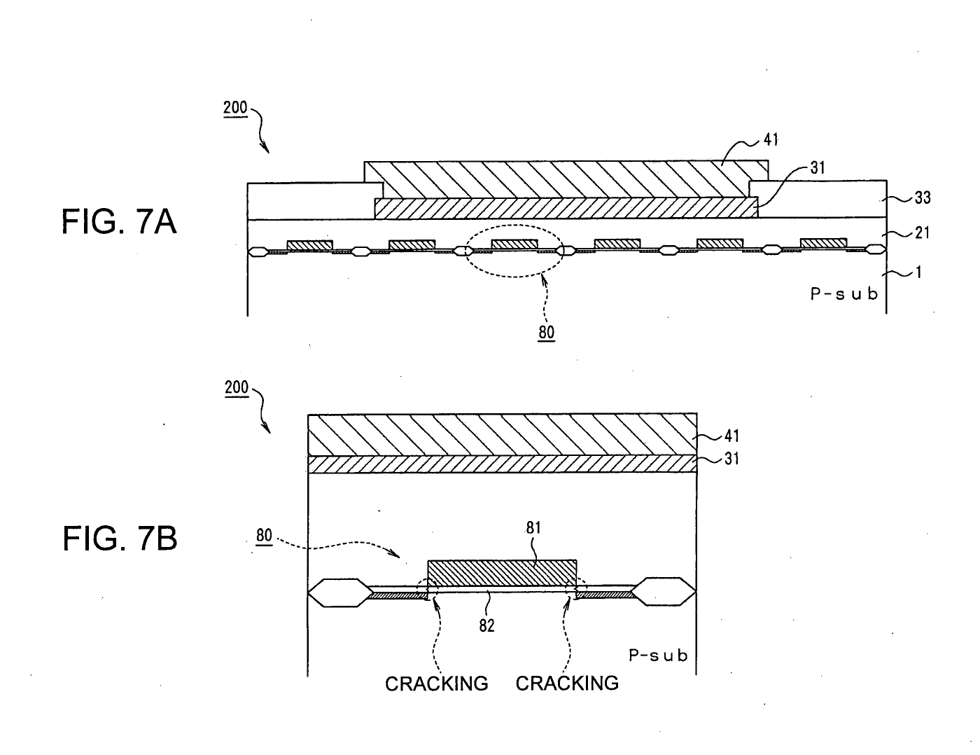

### DESCRIPTION OF EXEMPLARY EMBODIMENTS

Embodiments of the invention will now be described with references to the accompanying drawings.

### First Embodiment

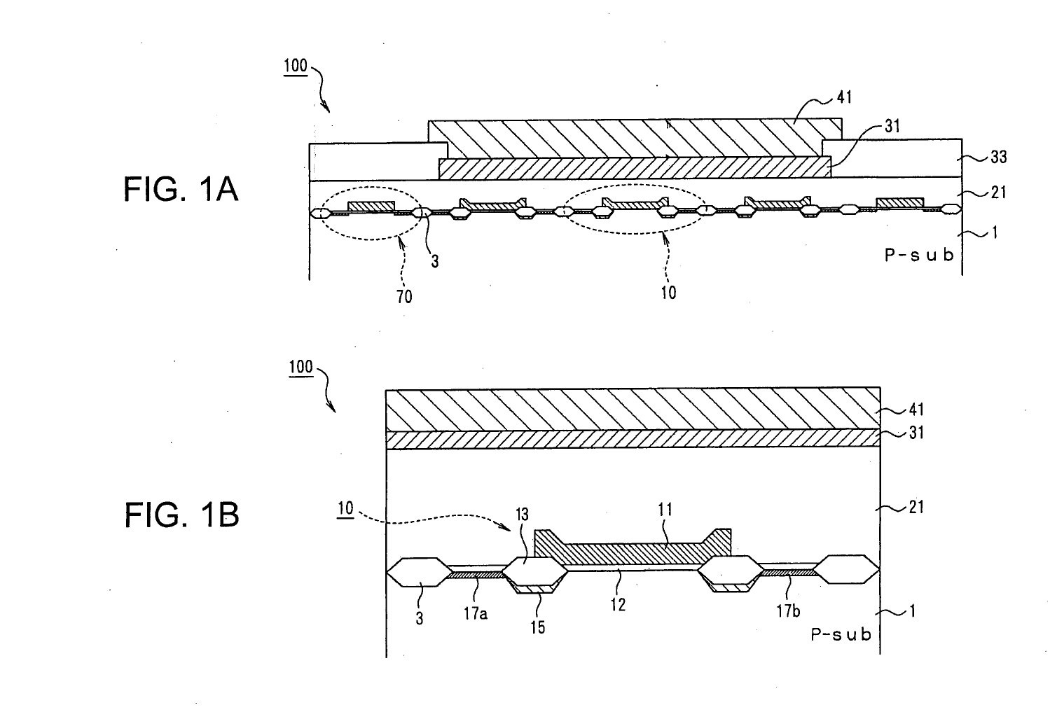

FIG. 1A is a sectional drawing showing an exemplary structure of a semiconductor device 100 according to a first embodiment of the invention. As shown in FIG. 1A, the semiconductor device 100 includes: a silicon substrate 1 (p-type substrate); two kinds of MOS transistors 10 and 70 formed on the silicon substrate 1; a LOCOS layer 3 that isolates elements into each MOS transistor 10 or MOS transistor 70; an interlayer insulation film 21, installed on the silicon substrate 1, covering the MOS transistors 10 and 70 as well as the LOCOS layer 3 and the like; an Al pad 31 installed on the interlayer insulation film 21; a passivation film 33, installed on the interlayer insulation film 21, covering the periphery of the top surface of the Al pad 31; and a bump electrode 41 installed on the Al pad 31 which is exposed beneath the passivation film 33.

The interlayer insulation film 21 is, for instance, composed with a silicon oxide film, and the passivation film 33 is a film in which the silicon oxide film and a silicon nitride film are deposited. In the semiconductor device 100, the reduction of chip area is achieved with a structure in which the Al pad 31 is formed above the MOS transistor 10 via the interlayer insulation film 21.

As shown in FIG. 1A, in this semiconductor device 100, the MOS transistor 10 is the only kind of transistor formed beneath the region in which the bump electrode 41 is formed (hereafter referred to as “bump region”), while the MOS transistor 70 is the only kind of transistor formed beneath the region in which the bump electrode 41 is not formed (hereafter referred to as “non-bump region”).

FIG. 1B is a sectional drawing showing an exemplary structure of the MOS transistor 10. The MOS transistor 10 shown in FIG. 1B includes a gate electrode 11, a gate oxide film 12, source or drain (hereafter referred to as “S/D”) layers 17a and 17b, a LOCOS offset layer 13, and an N-channel stopper (hereafter “NST”) layer 15. The gate electrode 11 is composed with polysilicon into which, for instance, arsenic is doped. The gate oxide film 12 is composed with, for instance, the silicon oxide film, and the thickness thereof is approximately in the range of 120 to 150 Å inclusive. Moreover, the S/D layers 17a and 17b are diffusion layers, formed by an N-type dopant such as arsenic or phosphorus being diffused into the silicon substrate 1.

The LOCOS offset layer 13 is the silicon oxide film installed into the silicon substrate 1, between the gate oxide film 12 and the S/D layer 17a, and between the gate oxide film 12 and the S/D layer 17b. As shown in FIG. 1B, in this MOS transistor 10, the LOCOS offset layer 13 is thicker than the gate oxide film 12, and because of this LOCOS offset layer 13, the silicon oxide film is thicker under the periphery of the gate electrode 11 than under the central area of the gate electrode 11. The thickness of the LOCOS offset layer 13 is, for instance, approximately in the range of 2000 to 4000 Å inclusive in this MOS transistor 10.

This NST layer 15 is a diffusion layer, formed by the N-type dopant such as arsenic or phosphorus being introduced and thermally diffused into the silicon substrate 1, over the LOCOS layer 3 offset layer. If a voltage higher than the designed threshold value is applied to the gate electrode 11, a channel that inverted to N-type is formed beneath the gate oxide film 12, and a drain current flows through this channel and the NST layer 15.

The described, the MOS transistor structure, in which only the silicon oxide film under the periphery of the gate electrode 11 is thickened by the LOCOS offset layer 13, is also called a LOCOS offset structure.

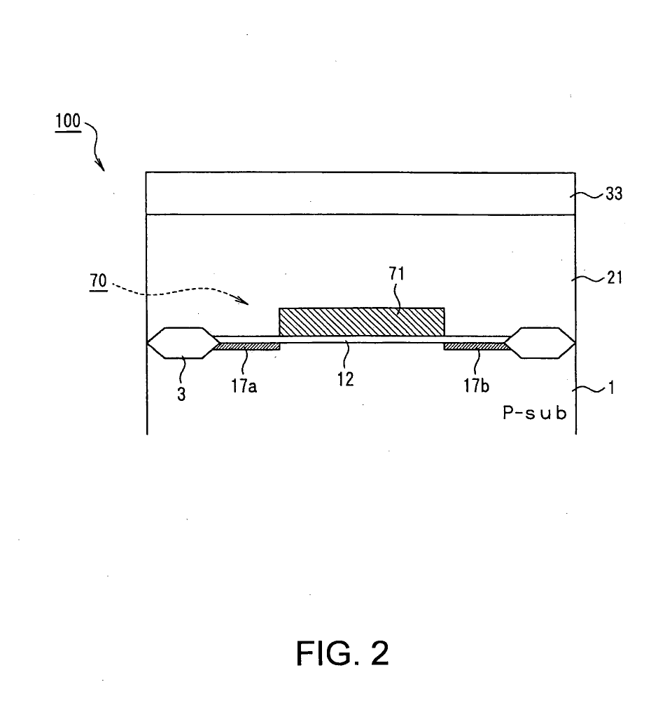

FIG. 2 is a sectional drawing showing an exemplary structure of the MOS transistor 70. As shown in FIG. 2, the MOS transistor 70 formed beneath the non-bump region has an ordinary structure, including a gate electrode 71, the gate oxide film 12, and the S/D layers 17a and 17b. There is no LOCOS offset layer 13 or the NST layer 15 in this MOS transistor 70, and only the gate oxide film 12 is formed between the gate electrode 71 and the silicon substrate 1. Hence, the thicknesses of the silicon oxide film under the central area of the gate electrode 71 and under the periphery of the gate electrode 71 are the same.

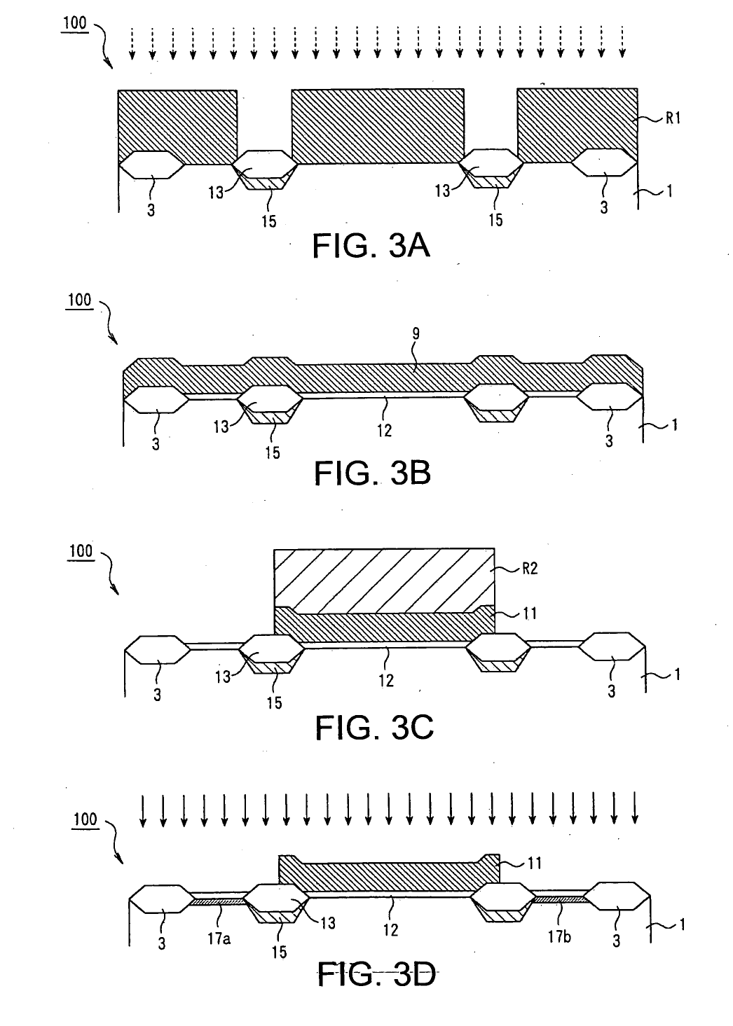

FIGS. 3A to D represent a flow chart showing a method for manufacturing the semiconductor device 100 according to the first embodiment of the invention. The method for manufacturing the semiconductor device 100 shown in FIGS. 1A and 1B will now be described.

In FIG. 3A, the LOCOS layer 3 and the LOCOS offset layer 13 is formed initially on the silicon substrate 1. Specifically, an oxidation resistant film (not shown) such as the silicon nitride film is partially formed on the silicon substrate 1, and the silicon substrate 1 is thermally-oxidized in this state. With this process, only the silicon substrate not covered by the oxidation resistant film is oxidized, and the LOCOS layer 3 and the LOCOS offset layer 13 are simultaneously formed. After forming the LOCOS layer 3 and the LOCOS offset layer 13, the oxidation resistant film is removed from the silicon substrate 1.

Thereafter, a resistive pattern (hereafter referred to as “first resistive pattern”) R1 that exposes the LOCOS offset layer 13 on the silicon substrate 1 and covers the rest of the region is formed by photolithography. Subsequently, as shown in FIG. 3A, the N-type dopant such as arsenic and phosphorus is introduced to the silicon substrate 1, using this first resistive pattern R1 as a mask. Further, the silicon substrate 1 undergoes thermal processing after removing the first resistive pattern R1. The NST layer 15 is formed on the silicon substrate 1, with ion implant and thermal diffusion.

Thereafter, the silicon substrate 1 is thermally-oxidized, and the gate oxide film 12 is formed as shown in FIG. 3B, followed by the formation of a polysilicon layer 9 on the entire surface of the silicon substrate 1 on which the gate oxide film 12 is formed. The formation of the polysilicon layer 9 is conducted by, for instance, low pressure chemical vapor deposition (LPCVD).

Subsequently, another resistive pattern (hereafter referred to as “second resistive pattern”) R2 is formed on the polysilicon film by photolithography. The second resistive pattern R2 covers only the region for forming the gate electrode for the MOS transistor 10 and the region for forming the gate electrode 71 (refer to FIG. 2), while leaving the rest of the region exposed. Then, as shown in FIG. 3C, the gate electrode 11 and the gate electrode 71 (refer to FIG. 2) are formed simultaneously by etching the polysilicon film using this second resistive pattern R2 as a mask.

Thereafter, the second resistive pattern R2 is removed. Subsequently, as shown in FIG. 3D, the S/D layers 17a and 17b are formed, by ion implant and thermal diffusion of an N-type dopant such as arsenic or phosphorus to the silicon substrate 1, using the gate electrodes 11 as a mask. Then, the interlayer insulation film 21 (refer to FIG. 1A) or a metal wiring (not shown) etc. are sequentially formed on the silicon substrate 1, on which the S/D layers 17a and 17b are formed, followed by the formation of the Al pad 31 (refer to FIG. 1A) on this interlayer insulation film 21.

This Al pad 31 is formed on the interlayer insulation film 21 above the MOS transistor 10 (or the bump region). Further, the passivation film 33 (refer to FIG. 1A) that has an orifice on the top of the Al pad 31 is formed on the interlayer insulation film 21, and then the bump electrode 41 (refer to FIG. 1A) on the Al pad 31 that is exposed beneath the passivation film 33 is formed. Consequently, the semiconductor device 100 shown in FIG. 1A is completed.

After forming the bump electrode 41, this semiconductor device 100 is packaged onto the wiring substrate. In this packaging process, the bump electrode 41 is adhered to an inner lead or outer lead of the wiring substrate with a thermocompression, applying a pressure in a high temperature. Therefore, a considerable amount of stress is applied to the MOS transistor 10 beneath the bump electrode 41 in this packaging process. However, in the semiconductor device 100 in the first embodiment, the stress during the packaging is resisted, since there is the LOCOS offset layer 13 under the periphery of the gate electrode in the MOS transistor 10, and this layer is thicker than the gate oxide film 12.

Hence the cracking under the periphery of the gate electrode 11, as well as the current leak through the crack, may be prevented, and this allows the provision of reliable and high quality integrated circuit products.

Further, in this semiconductor device 100, the thicknesses of the silicon oxide film under the central area of the gate electrode 11 of the MOS transistor 10 and under the central area of the gate electrode 71 are the same. In other words, the film thickness of the gate oxide film 12 is the same for the MOS transistors 10 and 70. Consequently, the electric characteristics such as the threshold voltage may be approximately the same for the MOS transistors 10 and 70.

Moreover, according to the method for manufacturing this semiconductor device 100, the silicon dioxide film under the periphery of the gate electrode 11 may be thickened simultaneously with the formation of the LOCOS layer 3 for component separation on the silicon substrate 1. Hence, only the small number of additional processes for film thickening is required.

The method for designing the semiconductor device 100, according to the first embodiment of the invention, includes: a process for detecting the location of the bump electrode 41; a process for identifying the transistors installed beneath the detected location; a process for defining only the identified transistors to the MOS transistor 10; and defining the rest of transistors to the MOS transistor 70.

This structure allows prevention: of cracking in the MOS transistor 10 installed beneath the bump region, caused by the stress during packaging; and of a current leak between the gate electrode 11 and the silicon substrate 1 though the crack.

In the first embodiment, the silicon substrate 1 corresponds to ‘semiconductor substrate’ and the Al pad 31 corresponds to ‘pad’ in the present invention. Further, the MOS transistor 10 corresponds to the ‘one kind of transistor’, and the MOS transistor 70 corresponds to ‘other kind of transistor’ in the present invention. Still further, the gate oxide film 12 and the LOCOS offset layer 13 correspond to ‘insulation film’ in the present invention.

### Second Embodiment

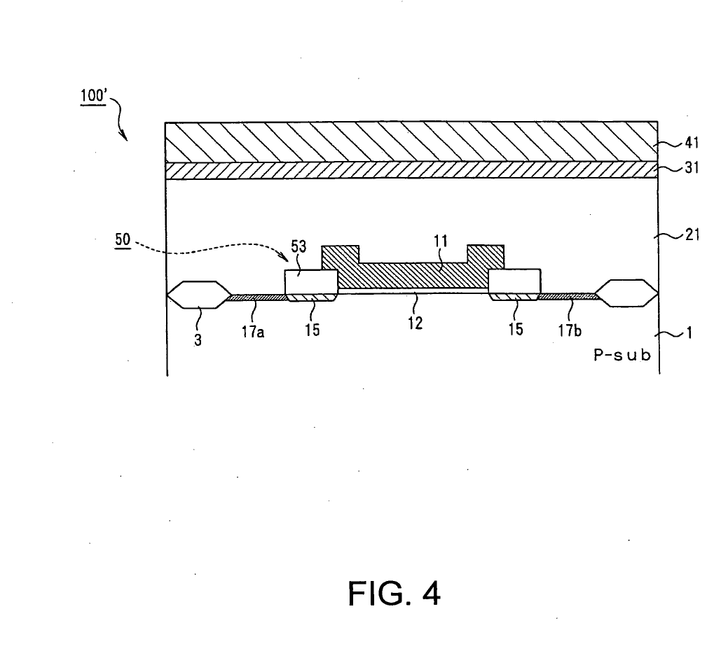

FIG. 4 is a sectional drawing showing an exemplary structure of a MOS transistor 50 in a second embodiment. The only difference between the first and the second embodiments is that the MOS transistor 10 with the LOCOS offset structure, in the semiconductor substrate 100 shown in FIG. 1A, is replaced with the MOS transistor 50 shown in FIG. 4. The rest of the structure is the same as that of the first embodiment. Thus, the same signs and numerals are used in FIG. 4 for the same structure as indicated in FIGS. 1A and 1B, and the overlapping description thereof is omitted.

The MOS transistor 50 shown in FIG. 4 includes the gate electrode 11, the gate oxide film 12, the S/D layers 17a and 17b, a HTO layer 53, and the NST layer 15. The HTO layer 53 is the silicon oxide film respectively installed on the silicon substrate 1, between the gate oxide film 12 and the S/D layer 17a, and between the gate oxide film 12 and the S/D layer 17b. As shown in FIG. 4, in this MOS transistor 50, the HTO layer 53 is thicker than the gate oxide film 12, and because of this HTO layer 53, the silicon oxide film is thicker under the periphery of the gate electrode 11 than under the central area of the gate electrode 11. The thickness of the HTO layer 53 is, for instance, approximately in the range of 2000 to 3000 Å inclusive in this MOS transistor 50.

The described, the MOS transistor structure, in which only the silicon oxide film under the periphery of the gate electrode 11 is thickened by the HTO layer 53, is called a HTO offset structure.

In a semiconductor device 100′ in a second embodiment, the MOS transistor 50, having the HTO offset structure, is the only kind of transistor formed beneath the bump region, and the MOS transistor 70 (refer to FIG. 2) of the ordinary structure, is the only kind of transistor formed beneath the non-bump region.

This structure allows prevention of cracking caused by the stress during packaging and a current leak through the crack, since there is the HTO layer 53 beneath the periphery of the gate electrode 11 of the MOS transistor 50, and this layer is thicker than the gate oxide film 12. Hence, this allows the provision of reliable and high quality integrated circuit products, as in the first embodiment.

The size of the element in the semiconductor device may be made smaller compared to the MOS transistor 10 described in the first embodiment, since there is no bird beak typically found in the LOCOS layer 3 of the MOS transistor 50. A method for manufacturing the semiconductor device 100′ that includes this MOS transistor 50 will now be explained.

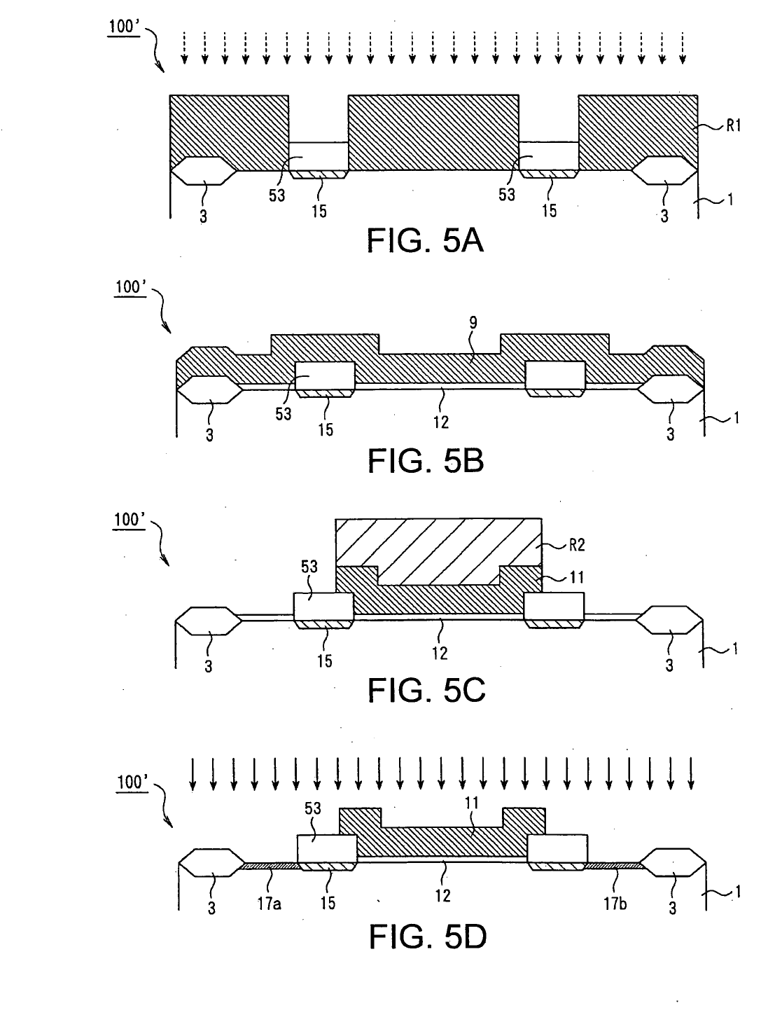

FIGS. 5A to D represent a flow chart showing a method for manufacturing the semiconductor device 100′ according to the second embodiment of the invention. In FIG. 5A, the LOCOS layer 3 is first formed initially on the silicon substrate 1. Thereafter, the HTO layer 53 is formed on the silicon substrate 1, on which the LOCOS layer 3 is formed. In forming the HTO layer 53, a silicon oxide film (not shown) is formed on the silicon substrate 1, with a method, for instance, a thermal CVD at 600 to 900 degrees Celsius, followed by the formation of, on this silicon oxide film, a resistive pattern (not shown) that covers a region where the HTO layer 53 will be formed and exposes the rest of the region. Finally, the formation of the HTO layer 53 is completed by etching the silicon oxide film using this resistive pattern as a mask.

Thereafter, as shown in FIG. 5A, the first resistive pattern R1 that exposes the HTO layer 53 on the silicon substrate 1 and covers the rest of the region is formed by photolithography. Thereafter, as shown in FIG. 5A, the N-type dopant such as arsenic and phosphorus is introduced to the silicon substrate 1, using the first resistive pattern R1 as a mask. Further, the silicon substrate 1 undergoes thermal processing after removing the first resistive pattern R1. The NST layer 15 is formed on the silicon substrate 1, with ion implant and thermal diffusion.

The rest of the manufacturing method is the same as that of the first embodiment. In other words, the gate oxide film 12 is formed, and thereafter the polysilicon film 9 is formed on the entire surface of the silicon substrate 1 on which the gate oxide film 12 is formed, as shown in FIG. 5B. Subsequently, as shown in FIG. 5C, the second resistive pattern R2 is formed on the polysilicon film. The second resistive pattern R2 covers only the region for forming the gate electrode 11 for the MOS transistor and the region for forming the gate electrode 71 (refer to FIG. 2), while leaving the rest of the region exposed. Then, the gate electrode 11 and the gate electrode 71 (refer to FIG. 2) are formed simultaneously by etching the polysilicon film using this second resistive pattern R2 as a mask.

Thereafter, as shown in FIG. 5D, the S/D layers 17a and 17b are formed, by ion implant and thermal diffusion of the N-type dopant such as arsenic or phosphorus to the silicon substrate 1, using the gate electrodes 11 as a mask. Thereafter, the interlayer insulation film 21 (refer to FIG. 1A) or the metal wiring (not shown) etc. are sequentially formed on the silicon substrate 1, on which the S/D layers 17a and 17b are formed, followed by the sequential formation of the Al pad 31 (refer to FIG. 1A) and the passivation film 33 (refer to FIG. 1A). Finally, the semiconductor device 100′ according to the second embodiment is completed by forming the bump electrode 41 (refer to FIG. 1A) on the Al pad 31 that is exposed beneath the passivation film 33.

In the second embodiment of the invention, the MOS transistor 50 corresponds to ‘one kind of transistor’, and the gate oxide film 12 and the HTO layer 53 correspond to ‘other kind of transistor’ in the present invention. The rest of the relationships of the elements are the same as that of the first embodiment

### Third Embodiment

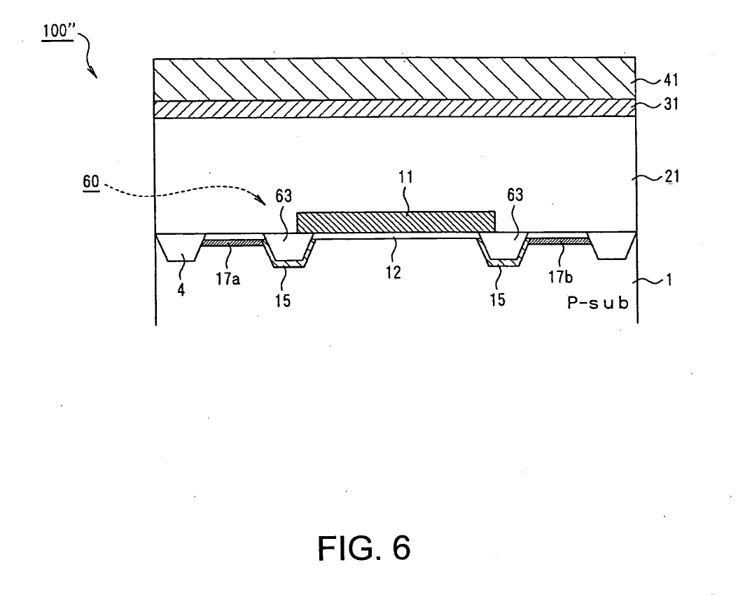

FIG. 6 is a sectional drawing showing an exemplary structure of a MOS transistor 60 in a third embodiment. The only difference between the first and the third embodiments is that the MOS transistor 10 with the LOCOS offset structure and the LOCOS layer 3 for component separation, in the semiconductor substrate 100 shown in FIG. 1A, are replaced with the MOS transistor 60 shown in FIG. 6 and a STI layer 4 for component separation. The rest of the structure is the same as that of the first embodiment. Thus, the same signs and numerals are used in FIG. 6 for the same structure as indicated in FIGS. 1A and 1B, and the overlapping description thereof is omitted.

The MOS transistor 60 shown in FIG. 6 includes the gate electrode 11, the gate oxide film 12, the S/D layers 17a and 17b, a STI offset layer 63, and the NST layer 15. The STI offset layer 63 is the silicon oxide film installed into the silicon substrate 1, between the gate oxide film 12 and the S/D layer 17a, and between the gate oxide film 12 and the S/D layer 17b.

As shown in FIG. 6, in this MOS transistor 60, the STI offset layer 63 is thicker than the gate oxide film 12, and because of this SIT offset layer 63, the silicon oxide film is thicker under the periphery of the gate electrode 11 than under the central area of the gate electrode 11. The thickness of the SIT offset layer 63 is, for instance, approximately in the range of 4000 to 7000 Å inclusive in this MOS transistor 60.

The described MOS transistor structure, in which only the silicon oxide film under the periphery of the gate electrode 11 is thickened by the STI offset layer 63, is also called a STI offset structure.

In a semiconductor device 100″ in the third embodiment, the MOS transistor 60, having the SIT offset structure, is the only kind of transistor formed beneath the bump region, and the MOS transistor 70 (refer to FIG. 2) of the ordinary structure, is the only kind of transistor formed beneath the non-bump region.

This structure allows prevention of cracking caused by the stress during packaging and a current leak through the crack, since there is the STI offset layer 63 beneath the periphery of the gate electrode 11 in the MOS transistor 60, and this layer is thicker than the gate oxide film 12. Hence, this allows the provision of reliable and high quality integrated circuit products, as in the first and the second embodiments.

The size of the element in the semiconductor device may be made smaller compared to the MOS transistor 10 described in the first embodiment, since there is no bird beak typically found in the LOCOS layer 3 of the MOS transistor 60.

Moreover, in forming this semiconductor device 100″, the silicon dioxide film under the periphery of the gate electrode 11 may be thickened simultaneously with the formation of the STI layer 4 for component separation on the silicon substrate 1. Hence, only the small number of additional processes for film thickening is required.

In the third embodiment of the invention, the MOS transistor 60 corresponds to ‘one kind of transistor’, and the gate oxide film 12 and the STI offset layer 63 correspond to ‘other kind of transistor’ in the present invention. The rest of the relationships of the elements are the same as that of the first embodiment.

What is claimed is:

1. A semiconductor device, comprising:
a semiconductor substrate;
a first gate insulation film installed on the semiconductor substrate;
a first gate electrode installed on the first insulation film;
a silicon oxide film, installed beneath a periphery of the first gate electrode, the silicon oxide film being thicker than the first gate insulation film, and the silicon oxide film being formed from a high temperature oxide;
a source and a drain installed on the semiconductor substrate;
an interlayer insulation film installed above the semiconductor substrate;
a pad electrode installed on the interlayer insulation film;
a passivation film, installed on the pad electrode, having an orifice above the pad electrode; and
a bump electrode, installed in the orifice, located vertically above the part of or the entire first gate electrode.
